(19) United States
(12) Patent Application Publication
(10) Pub. No.: US 2014/0048866 A1
(43) Pub. Date: Feb. 20, 2014

(54) GATE STRUCTURE AND METHOD OF MANUFACTURING THEREOF

(71) Applicants: Jeng Hwa Liao, Hsinchu City (TW); Jung Yu Shieh, Hsinchu City (TW); Ling Wuu Yang, Hsinchu City (TW)

(72) Inventors: Jeng Hwa Liao, Hsinchu City (TW); Jung Yu Shieh, Hsinchu City (TW); Ling Wuu Yang, Hsinchu City (TW)

(73) Assignee: MACRONIX INTERNATIONAL CO., LTD., Hsin-chu (TW)

(21) Appl. No.: 13/588,367

(22) Filed: Aug. 17, 2012

(51) Int. Cl. H01L 29/792; H01L 29/02; H01L 21/336

(52) U.S. Cl. 257/324; 438/591; 257/637; 257/E29.309; 257/E21.422; 257/E29.002

(57) ABSTRACT

An improved gate structure is provided whereby the gate structure is defined by a trench, the trench having a first oxide layer and a second oxide layer. The invention also provides methods for fabricating the gate structure of the invention defined by a trench having a first oxide layer and a second oxide layer.

### TECHNOLOGICAL FIELD

Embodiments of the present invention relate generally to a semiconductor device, in particular, a gate structure for a semiconductor device.

### BACKGROUND

Erasable programmable read-only memory (EPROM), electrically erasable read-only memory (EEPROM), and flash memory devices consist of a plurality of gate structures. These gate structures generally comprise a control gate and a floating gate that is positioned between the control gate and a substrate. The floating gate is a conductive layer normally fabricated of a polysilicon material. The floating gate is not attached to any electrodes or power sources and is itself generally surrounded by an insulation material.

The operation of EEPROM non-volatile memory devices, such as a floating gate tunnel oxide (FLOTOX) EEPROM, is dependent upon the charge stored in the floating gate at the threshold voltage needed to represent information stored in these devices.

The performance of EEPROM devices typically includes a performance specification or rating of the programming speed that influences the speed of erase and write operations. The speed is typically limited by the rate at which electrons can be pumped into (writing) and out of (erasing) the device without causing damage to the device. Typically, erasing and writing operations must be capable of operating within 1 msec at a specified applied voltage.

As the dimensions of memory devices continue to be reduced, the thickness of each of the layers must also be reduced. While, for example, a thinner tunneling oxide layer may increase data writing and erasing efficiency as well as speed, smaller tunneling oxide layers may be more susceptible to damage upon exposure to recording or erasing energies. There remains a need in the art for improved non-volatile memory (NVM) devices for responding to the demands created by the drive to achieve even smaller memory devices.

Smaller dimensions result in a decrease in distance between the floating gate and control gate. However, the oxide/nitride/oxide (ONO) dielectric layer deposited on the floating gate becomes more susceptible to current leakage as a result of the proximity of the control gate to the floating gate in these smaller structures. There remains a need in the art for memory devices and processing techniques to improve the product and operational performance of such devices especially as the dimensions of these devices continue to be reduced.

### BRIEF SUMMARY OF EXEMPLARY EMBODIMENTS

Embodiments of the present invention provide semiconductor devices, in particular, a gate liner structure for semiconductor devices.

An aspect of the invention provides a gate structure for a semiconductor device, or more specifically a memory device comprising a substrate, a first dielectric layer, and a first conductive layer disposed on the first dielectric layer. In an embodiment of the invention, the first conductive layer may be configured to function, for example, as a floating gate.

A trench is defined by a sidewall and a bottom, wherein the trench extends from and is adjacent to the first conductive layer, the first dielectric layer, and to the substrate. A second dielectric layer is disposed along the sidewall, and a third dielectric layer substantially fills a remaining open portion of the trench. Pursuant to this embodiment of the invention, a ratio of a thickness of the second dielectric layer and a width of the trench is from about 5% to about 15%.

In certain embodiments of the invention, an etching rate of the second dielectric layer is smaller than an etching rate of the third dielectric layer. In yet other embodiments of the invention, the second dielectric layer is a deposited oxide layer while the third dielectric layer is a spin-on-dielectric (SOD) oxide layer.

In some embodiments of the invention, a silicon ratio of the second dielectric layer is different from a silicon ratio of the third dielectric layer. In some embodiments of the invention, the second dielectric layer comprises an amorphous silicon oxide and the third dielectric layer is a thermal oxide layer.

According to certain embodiments of the invention, the gate structure comprises a second dielectric layer that only partially surrounds a sidewall of the first conductive layer. Furthermore, an upper portion of the second dielectric layer may remain uncovered by the third dielectric layer.

In some embodiments of the invention, the gate structure comprises a fourth dielectric layer, in certain embodiments, an oxide/nitride/oxide layer, substantially disposed across the gate structure. In certain embodiments of the invention, the gate structure additionally comprises a second conductive layer disposed across the fourth dielectric layer. In an embodiment of the invention, the second conductive layer may be configured to function as a control gate.

An aspect of the invention provides a method for the fabrication of a gate structure having the steps of providing a substrate, forming a first dielectric layer on the substrate, disposing a first conductive layer on the first dielectric layer, forming a trench adjacent to the first dielectric layer and the first conductive layer, forming a second dielectric layer along a sidewall of the trench, and forming a third dielectric layer over the second dielectric layer, wherein a ratio of a thickness of the second dielectric layer and a width of the trench is from about 5% to about 15%.

In certain embodiments of the invention, the method for fabrication of the gate structure may additionally comprise etching the second dielectric layer and the third dielectric layer. In certain embodiments of the invention, an etching rate of the second dielectric layer is smaller than the etching rate of the third dielectric layer.

According to an embodiment of the invention, the second dielectric layer covers a bottom of the trench and a lower portion of the sidewall of the trench. Further pursuant to this embodiment, the third dielectric layer is disposed on the second dielectric layer such that an upper portion of the second dielectric layer is unexposed or not covered by the third dielectric layer.

According to an embodiment of the invention, the second dielectric layer is a first oxide layer and the third dielectric layer is a second oxide layer. Further pursuant to this embodiment of the invention, the first oxide layer is applied using a deposition process and the second oxide layer is a spin-on-dielectric (SOD) oxide layer. In certain embodiments of the invention, a silicon ratio of the first oxide layer is different from a silicon ratio of the second oxide layer.

The method of fabrication of the gate structure may additionally comprise the step of disposing a fourth dielectric layer on the first conductive layer, the second dielectric layer, and the third dielectric layer. In certain embodiments of the invention, the fourth dielectric layer may be an oxide/nitride/oxide (ONO) laminated layer. Moreover, the method of fabrication of the gate structure may additionally comprise applying a second conductive layer across the fourth dielectric layer.

An aspect of the invention provides a semiconductor device comprising a trench that is defined by a stack structure, the trench having a first width, and a dielectric structure interposed within the trench, the dielectric structure having a protusion portion defined by a second width. According to an embodiment of the invention, a ratio of the second width to the first width is from about 5% to about 15%.

According to an embodiment of the invention, the semiconductor may further comprise a dielectric layer disposed across the stack structure and the dielectric structure. In certain embodiments of the invention, the dielectric layer may be an oxide/nitride/oxide (ONO) laminated layer. In certain embodiments of the invention, a conductive layer may be disposed across the dielectric layer. In certain embodiments of the invention, the protusion portion is a deposited oxide layer.

According to an embodiment of the invention, the dielectric structure has a concave portion that is proximate to a center of the trench. For example, in certain embodiments of the invention, the concave portion may be a spin-on-dielectric (SOD) oxide layer.

Another aspect of the invention further comprises product fabricated from the methods of embodiments of the invention.

These embodiments of the invention and other aspects and embodiments of the invention will become apparent upon review of the following description taken in conjunction with the accompanying drawings. The invention, though, is pointed out with particularity by the appended claims.

### BRIEF DESCRIPTION OF THE SEVERAL VIEWS OF THE DRAWING(S)

Having thus described the invention in general terms, reference will now be made to the accompanying drawings, which are not necessarily drawn to scale, and wherein:

FIG. 1A illustrates a layered cross section of a gate structure according to an embodiment of the invention;

FIG. 1B illustrates a cross section of a gate structure defined by a trench according to an embodiment of the invention;

FIG. 1C illustrates a cross section of a gate structure defined by a trench and a first oxide layer according to an embodiment of the invention;

FIG. 1D illustrates a cross section of a gate structure defined by a trench, a first oxide layer and a second oxide layer disposed in the trench according to an embodiment of the invention;

FIG. 1E illustrates a cross section of a gate structure defined by a trench, a first oxide layer and a second oxide layer disposed in the trench that has been etched according to an embodiment of the invention;

FIG. 1F illustrates a cross section of a gate structure defined by a trench, a first oxide layer and a second oxide disposed in the trench that has been etched further having an oxide/nitride/oxide layer applied thereupon according to an embodiment of the invention;

FIG. 1G illustrates a cross section of a gate structure defined by a trench, a first oxide layer and a second oxide disposed in the trench that has been etched, an oxide/nitride/oxide layer, and a second conductive layer applied thereupon according to an embodiment of the invention;

FIG. 2 illustrates a cross section of a trench and two gate structures according to an embodiment of the invention; and

FIG. 3 is a flowchart illustrating a process for fabricating a gate structure according to an embodiment of the invention.

### DETAILED DESCRIPTION

Some embodiments of the present invention will now be described more fully hereinafter with reference to the accompanying drawings, in which some, but not all embodiments of the invention are shown. Indeed, various embodiments of the invention may be embodied in many different forms and should not be construed as limited to the embodiments set forth herein; rather, these embodiments are provided so that this disclosure will satisfy applicable legal requirements.

As used in the specification and in the appended claims, the singular forms “a”, “an”, and “the” include plural referents unless the context clearly indicates otherwise. For example, reference to “a gate structure” includes a plurality of such gate structures.

Although specific terms are employed herein, they are used in a generic and descriptive sense only and not for purposes of limitation. All terms, including technical and scientific terms, as used herein, have the same meaning as commonly understood by one of ordinary skill in the art to which this invention belongs unless a term has been otherwise defined. It will be further understood that terms, such as those defined in commonly used dictionaries, should be interpreted as having a meaning as commonly understood by a person having ordinary skill in the art to which this invention belongs. It will be further understood that terms, such as those defined in commonly used dictionaries, should be interpreted as having a meaning that is consistent with their meaning in the context of the relevant art and the present disclosure. Such commonly used terms will not be interpreted in an idealized or overly formal sense unless the disclosure herein expressly so defines otherwise.

As used herein, “gate structure” refers to a component of a semiconductor device, such as a memory device. Non-limiting examples of memory devices include flash memory devices. Erasable programmable read-only memory (EPROM) and electrically erasable read-only memory (EEPROM) devices are non-limiting examples of flash memory devices. The gate structures of the invention may be a gate structure assembly capable of operating in memory devices or a sub-assembly of a component or components of such gate structures.

A gate structure generally may include a first conductive layer and a second conductive layer. In particular the first conductive layer may comprise a floating gate or a floating gate layer and the second conductive layer may comprise a control gate or a control gate layer. A plurality of these gate structure representations in a memory device is used to identify information, such as information that is needed by a processing system. A component of a gate structure may include an assembly comprising a floating gate. The floating gate is configured to hold a charge at a threshold voltage. Another component of a gate structure may include an assembly comprising a control gate.

A gate coupling ratio may be used as a measurement of the performance of a memory device. The gate coupling ratio, GCR, is defined according to equation (1) below.

$$GCR = \frac{{c}_{ONO}}{{c}_{ONO} + {c}_{TOX}} \qquad ( 1 )$$

where:

GCR=gate coupling ratio,

C_{ONO}=capacitance of oxide/nitride/oxide (ONO) dielectric layer, and

C_{TOX}=capacitance of tunnel oxide layer

For theoretical perfect coupling, the gate capacitance ratio is equal to 100%, which means that the capacitance of the tunnel oxide layer would be driven to zero. Generally, increasing the gate capacitance ratio lowers the operating voltage of the memory device and increases the speed of the memory device. However, smaller semiconductor devices demand smaller gate structures, and as the gate structure becomes reduced so does the capacitance of the ONO dielectric layer relative to the capacitance of the tunnel oxide layer. The reduced size of the ONO dielectric layer causes the control gate to become more proximate to the floating gate, which can lead to current leakage in the gate structure.

The gate structure of the invention and methods of manufacturing such devices results in a gate structure that reduces or eliminates the extent of current leakage that may be experienced by a gate structure. The invention provides a gate structure and methods of manufacturing such devices that substantially reduce or eliminate the extent of current leakage that could otherwise be experienced by a gate structure.

One embodiment of the invention provides a gate structure generally comprising a floating gate component of the gate structure having a first dielectric layer such as a tunnel oxide layer and a first conductive layer such as a floating gate layer, a trench comprising a sidewall and a bottom, a first oxide layer completely covering an outer surface of the first dielectric layer exposed at the sidewall and partially covering an outer surface of the first conductive layer exposed at the sidewall, and a second oxide layer filling a remaining portion of the trench. A dielectric layer, such as an oxide/nitride/oxide layer, is disposed across these defined elements of the gate structure. A gate structure for use in a semiconductor device may include the floating gate structure of the embodiment of the invention, a second conductive layer such as a control gate, and other optional layers.

In one embodiment of the invention, the first oxide layer comprises a first oxide, and the second oxide layer comprises a second oxide, where the first oxide and the second oxide are different. The second oxide may have advantageous gap-filling characteristics when used to form the second oxide isolation layer.

According to an embodiment of the invention, the first oxide and the second oxide are such that the etching rate of the first oxide layer is smaller than the etching rate of the second oxide layer. In an embodiment of the invention, the etching rate of the first oxide layer is at least about 30% less than the etching rate of the second oxide layer. In embodiments of the invention, the etching rate of the first oxide film is about ¾, about ½, and about ¼ of the etching rate of the second oxide film.

In an embodiment of the invention, the first oxide layer may be an oxide layer that has been applied using a deposition process while the second oxide layer is a spin-on-dielectric (SOD) oxide layer. Non-limiting examples of deposition processes include chemical vapor deposition, physical vapor deposition, atomic layer deposition, and molecular beam epitaxy. Examples of chemical vapor deposition include, but are not necessarily limited to, plasma-enhanced chemical vapor deposition (PECVD), plasma-assisted chemical vapor deposition (PACVD), plasma-promoted chemical vapor deposition (PPCVD), low pressure chemical vapor deposition (LPCVD), and atmospheric pressure chemical vapor deposition (APCVD).

The application of the first oxide layer using chemical vapor deposition may occur at any temperature know in the art to be suitable for chemical vapor deposition of an oxide layer. In example embodiments of the invention, a chemical vapor deposition may be carried out at any temperature in a range of from about 100° C. to about 750° C. In some example embodiments of the invention, high temperature process chemical deposition is carried out in a range of temperatures of from about 400° C. to about 700° C., from about 450° C. to about 700° C., from about 500° C. to about 700° C., from about 550° C. to about 700° C., and from about 600° C. to about 700° C. In other embodiments of the invention, the temperature of chemical vapor deposition can be in the range of from about 685° C. to about 715° C. The temperature at which chemical vapor deposition is carried out may depend upon the type of chemical vapor deposition.

The pressure at which the chemical vapor deposition is carried out may depend upon the type of chemical vapor deposition process. For example, the pressure at which chemical vapor deposition is carried out may be any pressure in the range of from about 0.2 torr to about 760 torr.

Deposition processes are typically followed by a post-deposition annealing process. Annealing is treatment of the device with heat to improve properties such as strength and hardness of the applied material. Annealing is typically carried out in an atmosphere that is substantially free of oxygen to prevent oxidation of the materials. For example, annealing may be conducted at any temperature in a range of from about 500° C. to about 1,200° C. and any pressure in a range of from about 0.2 torr to about 760 torr. Any atmosphere that is substantially free of oxygen may be used. Typical gases for annealing atmospheres include nitrogen, argon, hydrogen, etc. In certain embodiments of the invention, the annealing atmosphere may include oxygen.

In certain embodiments of the invention, the extent of or severity of thermal annealing may be increased to at least partially offset the extent of or severity of reoxidation to further assist with defining desired characteristics of the oxide layer.

In one embodiment of the invention, the first oxide layer and the second oxide layer are both deposition layers, but a silicon ratio of the first oxide layer is different from a silicon ratio of the second oxide layer. The silicon ratio of the first oxide layer may be greater than the silicon ratio of the second oxide layer. In another embodiment of the invention, the silicon ratio of the first oxide layer is less than the silicon ratio of the second oxide layer. In an embodiment of the invention, the silicon ratio of the first oxide layer compared to the silicon ratio of the second oxide layer is in a range of from about 3:1 to about 1:2.

According to one embodiment of the invention, the first oxide layer comprises an amorphous silicon oxide, and the second oxide layer is a thermal oxide layer.

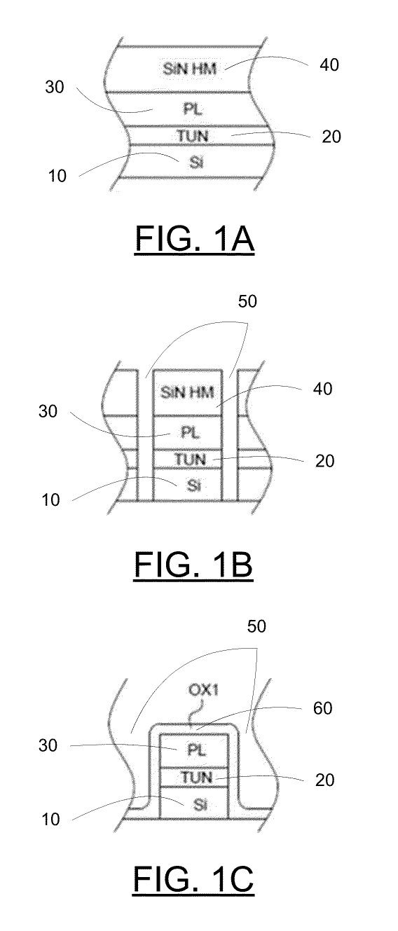

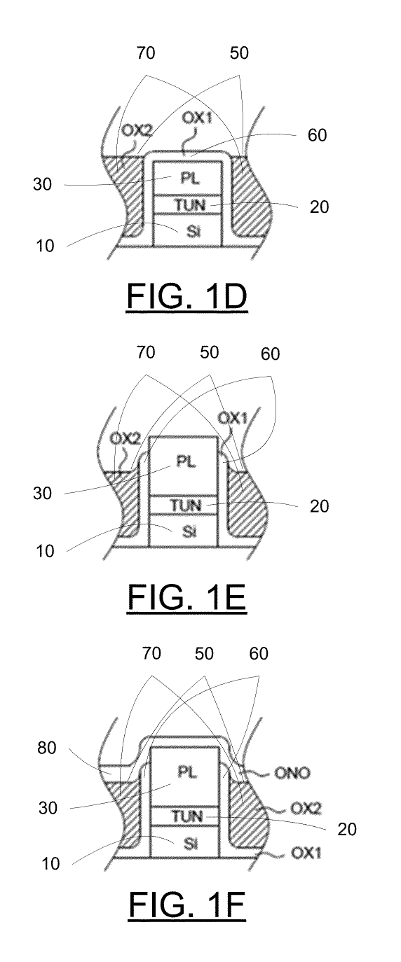

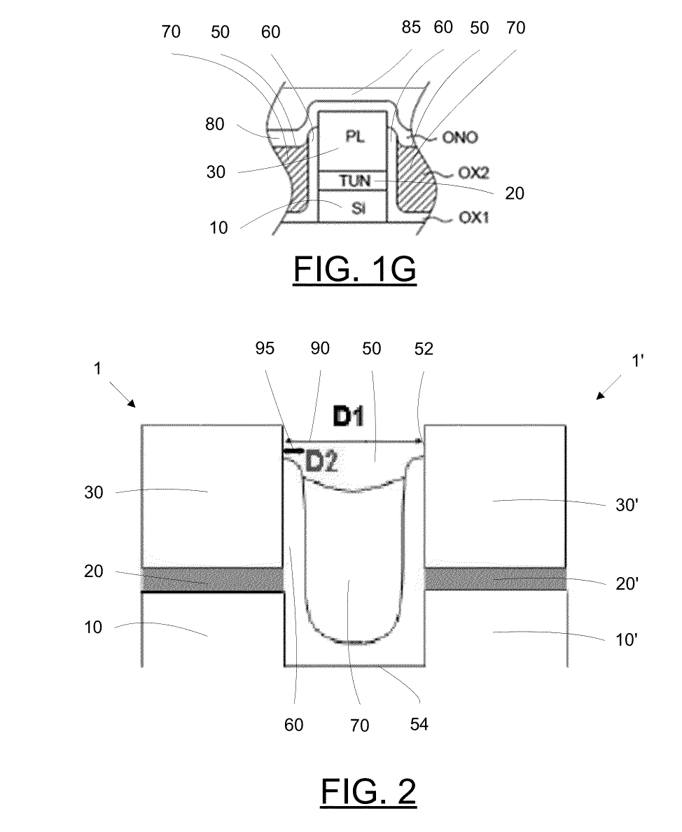

FIG. 1A illustrates a layered cross section of a gate structure according to an embodiment of the invention. According to this exemplary embodiment, the gate structure comprises a substrate that may be, as a non-limiting example, a silicon substrate 10, a first dielectric such as, for example, a tunnel oxide layer 20, a first conductive layer that may be a floating gate layer 30, and a mask layer that may be, as a non-limiting example, a SiN hard mask layer 40.

FIG. 1B illustrates a cross section of a gate structure defined by a trench according to an embodiment of the invention. The silicon nitride (SiN) hard mask layer 40 acts as a mask for the etching process that forms a trench that defines a trench 50. According to an embodiment of the invention, the trench is defined by a sidewall and a bottom, wherein the sidewall may surrounds the first dielectric layer and the first conductive layer. The sidewall may surround an exposed portion of the substrate at the sidewall, the first dielectric layer, and the first conductive layer according to another exemplary embodiment.

The SiN hard mask layer 40 may be removed prior to depositing, for example, a first oxide layer conformally across a surface of this floating gate component of the gate structure. FIG. 1C illustrates a cross section of the gate structure defined by the trench 50 and a second dielectric layer 60, which, according to certain embodiments of the invention, may be an oxide layer or even a first oxide layer, deposited substantially along the surface of the floating gate component of the gate structure after the SiN hard mask layer has been removed.

FIG. 1D illustrates a cross section of the gate structure defined by the trench 50, the second dielectric layer 60, and a third dielectric layer 70, which, according to certain embodiments of the invention, may be an oxide layer or a second oxide layer, disposed in the trench 50. The second oxide layer 70 may substantially fill the remaining open portion of the trench 50. As further disclosed herein, the second oxide layer 70 may be applied to the remaining open portion of the trench 50 by deposition, but may be applied by SOD and/or thermal techniques.

FIG. 1E illustrates a cross section of the gate structure defined by the trench 50, the second dielectric layer 60 that is, for example, a first oxide layer and the third dielectric layer 70 that is, for example, a second oxide layer disposed in the trench 50 has been subjected to an etching process. In one embodiment of the invention, the etch rate of the first oxide layer 60 is less than the etch rate of the second oxide layer 70. According to the illustrated embodiment, the first oxide layer 60 only partially surrounds the outer layer of the floating gate layer 30 that is exposed to the trench 50 after etching while still fully surrounding the tunnel oxide layer 20 and the silicon substrate 10. In an embodiment of the invention, at least about 50% of the outer surface of the floating gate layer 30 exposed at the sidewall of the trench 50 remains uncovered by the first oxide layer 60 after etching. In one example embodiment of the invention, at least about 70% of the outer surface of the floating gate layer 30 exposed at the sidewall of the trench 50 remains uncovered by the first oxide layer 60 after etching.

Further pursuant to this embodiment of the invention, the second oxide layer 70 will leave only an outer surface of an upper portion of the first oxide layer 60 that remains uncovered by the second oxide layer 70 after etching. In some embodiments of the invention, at most about 50% of the upper height of the first oxide layer 60 as measured from the substrate (or bottom of the tunnel oxide layer 20) remains uncovered by the second oxide layer 70 after etching. In one example embodiment of the invention, anywhere from about 50% to about 100% of the upper height of the first oxide layer 60 as measure from the substrate (or bottom of the tunnel oxide layer 20) remains uncovered by the second oxide layer 70 after etching.

FIG. 1F illustrates a cross section of the gate structure where a fourth dielectric layer has been applied to the gate structure. In one embodiment, the fourth dielectric layer comprises an oxide/nitride/oxide (ONO) layer 80, i.e., a dielectric layer that is similar to a lamination structure having multiple layers including a lower oxide film, a nitride film, and an upper oxide film. According to exemplary embodiment illustrated by FIG. 1F, the second fourth layer will be substantially disposed on the open surfaces of the first conductive layer, the first oxide layer, and the second oxide layer.

Additional layers may be applied to the structure represented by FIG. 1F. In an embodiment of the invention a second conductive layer 85 may be applied to the fourth dielectric layer as illustrated, of example, in the exemplary illustrative embodiment of FIG. 1G. In an embodiment of the invention, the second conductive layer 85 may function, for example, as a control gate. Further pursuant to this exemplary embodiment, the trench 50 having a width and the first oxide layer 60 having a thickness. A ratio of the thickness to the width is from about 5% to about 15%. Without intending to be bound by theory, the ratio within this range provides sufficient spacing between the second conductive layer 85 and the first conductive layer 30 such that current leakage is substantially avoided.

FIG. 2 illustrates a cross section of a trench and two gate structures according to an embodiment of the invention. The embodiment represented by FIG. 2 is representative of a shallow trench isolation having a stair profile. The exemplary embodiment of FIG. 2 shows two gates 1 and 1′ each respectively having a substrate 10 and 10′, a first dielectric layer 20 and 20′, and a first conductive layer 30 and 30′. According to certain embodiments of the invention, the first dielectric layer 20 and 20′ may be a tunnel oxide layer and the first conductive layer 30 and 30′ may be a floating gate layer. The gates are surrounded by a trench 50 defined by a sidewall 52 and a bottom 54. The distance D₁ is identified by line 90 and represents a pitch or width of the trench 50 between the two gates 1 and 1′.

The trench 50 having a first oxide layer 60 and a second oxide layer 70. The first oxide layer 60 defines a spacer mostly disposed along the sidewall 52 and continuing along the bottom 54 of the trench 50. The spacer tapers as it projects from the sidewall 52 until forming a substantially constant thickness along the sidewall 52. The distance D₂ is identified by line 95 and represents the substantially constant thickness of the spacer or the first oxide layer 60 as it continues down the sidewall 52. As the spacer approaches the bottom 54 of the trench 50, the thickness of the first oxide layer 60 may begin to increase. The spacer may generally define a void about a center of the spacer. The second oxide layer 70 may substantially fill the void defined by the spacer. In certain embodiments of the invention, the second oxide layer 70 only partially fills the void to define a “stair” profile as illustrated in the exemplary embodiment of FIG. 2. In certain embodiments of the invention, the second oxide layer 70 may only fill the void to about the point where the first oxide layer 60 forms the substantially constant thickness. The bottom begins at a top of the second oxide layer 70, progresses to the first oxide layer 60 as it tapers from the first conductive layer 30 and 30′, and continues along a sidewall portion of the trench 50 along the first conductive layer 30 an 30′ that is substantially free of the first oxide layer 60.

In an embodiment of the invention, D₂ is from about 5% to about 15% of the value of D₁. According to a certain embodiment of the invention, D₂ is from about 7% to about 12% of the value of D₁. Without intending to be bound by the theory, a D₂/D₁ ratio from about 7% to about 12% substantially suppresses any current leakage between a first conductive layer, for example a floating gate, and a subsequently applied second conductive layer, for example a control gate, as further disclosed herein.

More generally and similar to the illustrative embodiment of FIG. 2, a semiconductor device may comprise a trench 50 that is defined by two stack structures 1 & 1′, the trench 50 having a dielectric structure. In certain embodiments of the invention, the dielectric structure may have a stair profile, as further shown in FIG. 2, adjacent to a sidewall of the stack structures 1 & 1′. In an exemplary embodiment of the invention, the dielectric structure may have an edge region and a center region. Further pursuant to this exemplary embodiment, a height of the edge region 60 is greater than the height of the center region 70 further defining the stair profile along the sidewall of the stack structures 1 & 1′.

According to an embodiment of the invention, the edge region 60 may form a substantially constant thickness, D₂, 95 along the sidewall of the two stack structures 1 & 1′ and the trench 50 having a width, D₁, 90 that is the distance between the two stack structures 1 & 1′. In an embodiment of the invention, a ratio of the substantially constant thickness 95 of the edge region 60 to the width 90 of the trench 50 is in a range of about 5% to about 15%.

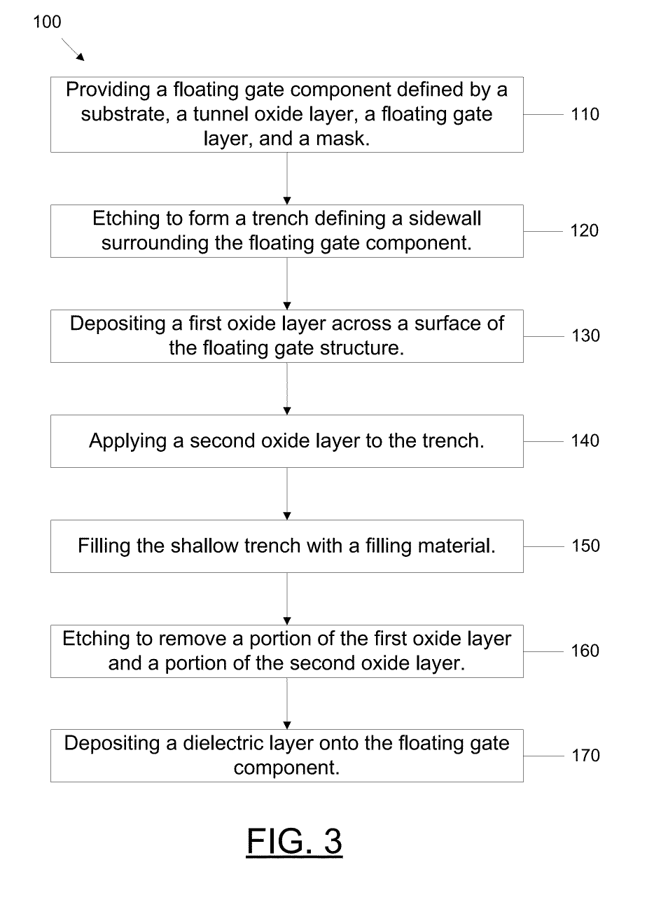

FIG. 3 is a flowchart illustrating a process for fabricating a gate structure according to an embodiment of the invention. The process for fabricating a gate structure 100 comprises the step of providing a first conductive component or a floating gate component 110. A first conductive component, as described herein, may comprise a substrate, having a dielectric layer or a tunnel oxide layer, and followed by a first conductive layer or a floating gate layer disposed there upon. A mask may define a trench that surrounds the floating gate component, which is formed upon etching.

The process for fabricating a gate structure 100 additionally comprises etching to form the trench having a sidewall and a bottom, the sidewall surrounding the first conductive component or the floating gate component 120 and depositing a first oxide layer across a surface of the first conductive component or the floating gate structure 130. Optionally, the mask used in forming the trench that defines the sidewall may be removed before depositing the first oxide layer across the surface of the gate structure 130.

The process for fabricating a gate structure 100 further comprises the step of applying a second oxide layer to the trench 140. The second oxide layer may be applied to substantially fill the remaining open portion of the trench. This step will then be followed by the step of etching the first oxide layer and the second oxide layer. The etch rate of the first oxide layer may be less than the etch rate of the second oxide layer such that a portion of the outer surface of the first oxide layer remains uncovered by the second oxide layer after etching.

The process for fabricating a gate structure 100 includes the step of etching to remove a portion of the first oxide layer and a portion of the second oxide layer 160. The first oxide layer and the second oxide layer may be such that only an outer surface of an upper portion of the first oxide layer remains uncovered by the second oxide layer after etching.

After etching, the process for fabricating a gate structure 100 comprises the step of depositing a second dielectric layer onto the first conductive component or the floating gate component. The second dielectric layer may be an oxide/nitride/oxide dielectric layer.

Following these steps, any additional steps known in the art may be used to finalize the fabrication of the gate layer. Such steps will of course include forming a second conductive layer or a control gate layer and may include other additional steps depending upon the design and desired attributes of the gate structure.

An aspect of the invention provides a gate structure fabricated according to a method of the invention.

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed and that modifications and other embodiments are intended to be included within the scope of the appended claims. Moreover, although the foregoing descriptions and the associated drawings describe exemplary embodiments in the context of certain exemplary combinations of elements and/or functions, it should be appreciated that different combinations of elements and/or functions may be provided by alternative embodiments without departing from the scope of the appended claims. In this regard, for example, different combinations of elements and/or functions than those explicitly described above are also contemplated as may be set forth in some of the appended claims. Although specific terms are employed herein, they are used in a generic and descriptive sense only and not for purposes of limitation.

1. A gate structure for a semiconductor device comprising:
a substrate;
a first dielectric layer disposed on the substrate;
a first conductive layer disposed on the dielectric layer
a trench adjacent to the first dielectric layer and the first conductive layer, the trench having a first sidewall;
a second dielectric layer disposed along the first sidewall of the trench; and
a third dielectric layer interposed in and substantially filling a remaining open portion of the trench,
wherein a ratio of a thickness of the second dielectric layer and a width of the trench is from about 5% to about 15%.

2. The gate structure of claim 1, wherein an etching rate of the second dielectric layer is smaller than an etching rate of the third dielectric layer.

3. The gate structure of claim 1, wherein the second dielectric layer is a deposited oxide layer and the third dielectric layer is a spin-on-dielectric (SOD) oxide layer.

4. The gate structure of claim 1, wherein a silicon ratio of the second dielectric layer is different from a silicon ratio of the third dielectric layer.

5. The gate structure of claim 1, wherein the second dielectric layer comprises an amorphous silicon oxide and the third dielectric layer is a thermal oxide layer.

6. The gate structure of claim 1, wherein the second dielectric layer only partially surrounds a second sidewall of the first conductive layer.

7. The gate structure of claim 6, wherein an upper portion of the second dielectric layer remains uncovered by the third dielectric layer.

8. The gate structure of claim 2, additionally comprising a fourth dielectric layer disposed on the first conductive layer, the second dielectric layer, and the third dielectric layer.

9. The gate structure of claim 8, wherein the fourth dielectric layer is an oxide/nitride/oxide (ONO) laminated layer.

10. The gate structure of claim 8, additionally comprising a second conductive layer disposed on the fourth dielectric layer.

11. A method for the fabrication of a gate structure comprising:
providing a substrate;
forming a first dielectric layer on the substrate;
disposing a first conductive layer on the first dielectric layer;
forming a trench adjacent to the first dielectric layer and the first conductive layer;
forming a second dielectric layer along a sidewall of the trench and
forming a third dielectric layer over the second dielectric layer,
wherein a ratio of a thickness of the second dielectric layer and a width of the trench is from about 5% to about 15%.

12. The method of claim 11, additionally comprising etching the second dielectric layer and the third dielectric layer.

13. The method of claim 11, wherein an etching rate of the second dielectric layer is smaller than an etching rate of the third dielectric layer.

14. The method of claim 11, wherein the second dielectric layer covers a bottom of the trench and a lower portion of the sidewall of the trench.

15. The method of claim 14, wherein the third dielectric layer is disposed on the second dielectric layer leaving an upper portion of the second dielectric layer uncovered.

16. The method of claim 11, wherein the second dielectric layer is a first oxide layer and the third dielectric layer is a second oxide layer.

17. The method of claim 16, wherein the first oxide layer is applied using a deposition process and the second oxide layer is a spin-on-dielectric (SOD) oxide layer.

18. The method of claim 16, wherein a silicon ratio of the first oxide layer is different from a silicon ratio of the second oxide layer.

19. The method of claim 11 additionally comprising disposing a fourth dielectric layer on the first conductive layer, the second dielectric layer, and the third dielectric layer.

20. The method of claim 19, wherein the fourth dielectric layer is an oxide/nitride/oxide (ONO) laminated layer.

21. The method of claim 19, additionally comprising applying a second conductive layer on the fourth dielectric layer.

22. A semiconductor device comprising:
a trench defined by a stack structure, the trench having a first width and
a dielectric structure interposed in the trench, the dielectric structure including a protusion portion having a second width,
wherein a ratio of the second width to the first width is from about 5% to about 15%.

23. The semiconductor of claim 22, further comprising a dielectric layer located on the stack structure and the dielectric structure.

24. The semiconductor of claim 23, wherein the dielectric layer is an oxide/nitride/oxide (ONO) laminated layer.

25. The semiconductor of claim 23, further comprising a conductive layer disposed on the dielectric layer.

26. The semiconductor of claim 22, wherein the protusion portion is a deposited oxide layer.

27. The semiconductor of claim 22, wherein the dielectric structure has a concave portion proximate to a center of the trench.

28. The semiconductor of claim 27, wherein the concave portion is a spin-on-dielectric (SOD) oxide layer.
